(19) United States
(12) Patent Application Publication
(10) Pub. No.: US 2023/0205954 A1
(43) Pub. Date: Jun. 29, 2023

(54) APPARATUS AND METHOD FOR REINFORCEMENT LEARNING FOR OBJECT POSITION OPTIMIZATION BASED ON SEMICONDUCTOR DESIGN DATA

(71) Applicant: AGILESODA INC., Seoul (KR)

(72) Inventors: Pham-Tuyen LE, Suwon-si (KR); Ye-Rin MIN, Namyangju-si (KR); JunHo KIM, Seoul (KR); DoKyoon YOON, Seoul (KR); KyuWon CHOI, Seongnam-si (KR)

(73) Assignee: AGILESODA INC., Seoul (KR)

(21) Appl. No.: 18/082,823

(22) Filed: Dec. 16, 2022

(30) Foreign Application Priority Data
Dec. 28, 2021 (KR) 10-2021-0190143

(51) Int. Cl. G06F 30/27; G06F 18/21; G06F 30/18

(52) U.S. Cl. CPC G06F 30/27; G06F 18/217; G06F 30/18

(57) ABSTRACT

Disclosed are an apparatus and a method for reinforcement learning for semiconductor element position optimization based on semiconductor design data. According to the present disclosure, a learning environment may be constructed based on a user's semiconductor design data such that optimal positions of semiconductor elements are provided during a semiconductor design process through reinforcement learning using simulation.

### CROSS-REFERENCE TO RELATED APPLICATION(S)

This application is based on and claims priority under 35 U.S.C. 119 to Korean Patent Application No. 10-2021-0190143, filed on Dec. 28, 2021, in the Korean Intellectual Property Office, the disclosure of which is herein incorporated by reference in its entirety.

### BACKGROUND OF THE INVENTION

### 1. Field of the Invention

The present disclosure relates to an apparatus and a method for reinforcement learning for semiconductor element position optimization based on semiconductor design data and, more specifically, to an apparatus and a method for reinforcement learning for object position optimization based on semiconductor design data, wherein a learning environment is constructed based on a user's semiconductor design data, and optimal positions of semiconductor elements are determined during a semiconductor design process through reinforcement learning using simulation.

### 2. Description of the Prior Art

Semiconductor design steps are needed to manufacture semiconductors.

Various conditions need to be satisfied to fabricate semiconductors as ordered, and operators conduct manual design in design steps.

Operators need to find optimal positions and conduct design in connection with manually disposing semiconductor elements. This poses a problem in that necessary working hours and manpower are increased, and working efficiencies are substantially low.

In addition, each operator has different know-how, making the results of mass production inconsistent.

Reinforcement learning refers to a learning method that handles an agent who interacts with an environment and accomplishes an objective, and is widely used in the artificial intelligence field.

The purpose of such reinforcement learning is to find out what behavior a reinforcement learning agent (subject of learning behaviors) needs to do such that more rewards are given thereto.

That is, it is learned what is to be done to maximize rewards even without fixed answers. Instead of hearing what behavior is to be done in advance and then doing the same in situation having a clear relation between input and output, processes for learning how to maximize rewards through trial and error are undertaken.

In addition, the agent selects successive actions as time steps elapse, and will be rewarded based on the influence exerted on the environment by the actions.

FIG. 1 is a block diagram illustrating the configuration of a reinforcement learning apparatus according to the prior art. As illustrated in FIG. 1, the agent 10 learns a method for determining an action A (or behavior) by learning a reinforcement learning model, each action A influences the next state S, and the degree of success may be measured in terms of the reward R.

That is, the reward is a point of reward for the action (behavior) determined by the agent 10 according to a specific state when learning proceeds through a reinforcement learning model, and is a kind of feedback related to the decision making by the agent 10 as a result of learning.

The environment 20 is a set of rules related to behaviors that the agent 10 may take, rewards therefor, and the like. States, actions, and rewards constitute the environment, and everything determined, except the agent 10, corresponds to the environment.

Meanwhile, the agent 10 takes actions to maximize future rewards through reinforcement learning, and the result of learning is heavily influenced by how the rewards are determined.

### SUMMARY OF THE INVENTION

In order to solve the above-mentioned problems, it is an aspect of the present disclosure to provide an apparatus and a method for reinforcement learning for object position optimization based on semiconductor design data, wherein a learning environment is constructed based on a user's semiconductor design data, and optimal positions of semiconductor elements are determined during a design or manufacturing process through reinforcement learning using simulation.

In accordance with an aspect of the present disclosure, an apparatus for reinforcement learning for object position optimization based on semiconductor design data according to an embodiment may include: a simulation engine configured to analyze object information including a semiconductor element and a standard cell based on design data including semiconductor netlist information, generate simulation data constituting a reinforcement learning environment having specific constrains configured with regard to individual analyzed objects, request optimization information for at least one semiconductor element disposition, perform simulation regarding disposition of the semiconductor element and the standard cell based on an action received from a reinforcement learning agent and state information including disposition information of the semiconductor element and the standard cell to be used for reinforcement learning, and provide reward information calculated based on connection information of the semiconductor element and the standard cell according to a simulation result as feedback regarding decision making by the reinforcement learning agent; a reinforcement learning agent configured to perform reinforcement learning based on state information and reward information received from the simulation engine, thereby determining an action so as to optimize disposition of the semiconductor element and the standard cell; and a design data portion configured to provide design data including semiconductor netlist information to the simulation engine, wherein the simulation engine generates, as reward information, distances by considering semiconductor element sizes according to a simulation result and provides the reward information to the reinforcement learning agent, and wherein the reinforcement learning agent determines an action through learning using a reinforcement learning algorithm such that the semiconductor elements are disposed in optimal positions, by reflecting the reward information in distances from already-disposed semiconductor elements, positional relation, and lengths of wires connecting semiconductor elements and standard cells.

In addition, according to the embodiment, the design data may be a semiconductor data file including CAD data or netlist data.

In addition, according to the embodiment, the simulation engine may have application program additionally installed for web-based visualization.

In addition, according to the embodiment, the simulation engine may further include: a reinforcement learning environment construction portion configured to analyze object information including semiconductor elements and standard cells based on design data including semiconductor netlist information, generate simulation data constituting a reinforcement learning environment and specific constraints with regard to individual objects, and request the reinforcement learning agent, based on the simulation data, to provide optimization information for at least one semiconductor element disposition; and a simulation portion configured to perform simulation regarding disposition of semiconductor elements and standard cells based on actions received from the reinforcement learning agent, calculate reward information based on connection information of the semiconductor elements and the standard cells according to a simulation result as feedback regarding decision making by the reinforcement learning agent and state information including disposition information of semiconductor elements and standard cells to be used for reinforcement learning, generate, as the reward information, distances by considering semiconductor element sizes according to the simulation result, and provide the reward information to the reinforcement learning agent.

In addition, according to the embodiment, the reward information may be calculated based on connection information of semiconductor elements and standard cells.

In addition, a method for reinforcement learning for semiconductor element position optimization based on semiconductor design data according to an embodiment of the present disclosure may include the steps of: a) analyzing, by a simulation engine, object information including a semiconductor element and a standard cell when design data including semiconductor netlist information is uploaded, thereby generating simulation data constituting a reinforcement learning environment having specific constrains configured with regard to individual analyzed objects; b) performing reinforcement learning, by a reinforcement learning agent, based on reward information and state information including disposition information of the semiconductor element and the standard cell to be used for reinforcement learning, collected from the simulation engine, upon receiving an optimization request for disposition of the semiconductor element and the standard cell based on simulation data constituting a reinforcement learning environment from the simulation engine, thereby determining an action so as to optimize disposition of the semiconductor element and the standard cell; and c) performing, by the simulation engine, simulation constituting a reinforcement learning environment regarding the semiconductor element and the standard cell based on an action received from the reinforcement learning agent, and providing the reinforcement learning agent with state information including disposition information of the semiconductor element and the standard cell to be used for reinforcement learning, and reward information calculated based on connection information of the semiconductor element and the standard cell according to a simulation result as feedback regarding decision making by the reinforcement learning agent, wherein the simulation engine generates, as reward information, distances by considering semiconductor element sizes according to the simulation result and provides the reward information to the reinforcement learning agent, and wherein the reinforcement learning agent determines an action through learning using a reinforcement learning algorithm such that the semiconductor elements are disposed in optimal positions, by reflecting the reward information in distances from already-disposed semiconductor elements, positional relation, and lengths of wires connecting semiconductor elements and standard cells.

In addition, according to the embodiment, the design data in step a) may be a semiconductor data file including CAD data or netlist data.

In addition, according to the embodiment, the method may further include a step of converting the simulation data in step a) to an eXtensible Markup Language (XML) file to be used through a web.

The present disclosure is advantageous in that a learning environment is constructed based on a user's semiconductor design data, and optimal positions of semiconductor elements can thus be determined and provided during a semiconductor design process through reinforcement learning using simulation.

In addition, the present disclosure is advantageous in that, when a user conducts semiconductor design, a learning environment similar to the actual environment is provided based on data designed by the user, thereby improving design accuracy.

In addition, the present disclosure is advantageous in that optimized semiconductor element positions are automatically determined through reinforcement learning based on data designed by the user, thereby improving work efficiency.

In addition, the present disclosure is advantageous in that different know-bows of operators are unified, thereby minimizing the deviation in resulting products, and guaranteeing mass production of the same quality of products.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a block diagram illustrating the configuration of a conventional reinforcement learning apparatus;

FIG. 2 is a block diagram illustrating the configuration of an apparatus for reinforcement learning for object position optimization based on semiconductor design data according to an embodiment of the present disclosure;

FIG. 3 is a block diagram illustrating the configuration of a simulation engine of the apparatus for reinforcement learning for object position optimization based on semiconductor design data according to the embodiment in FIG. 2; and

FIG. 4 is a flowchart illustrating a method for reinforcement learning for object position optimization based on semiconductor design data according to an embodiment of the present disclosure.

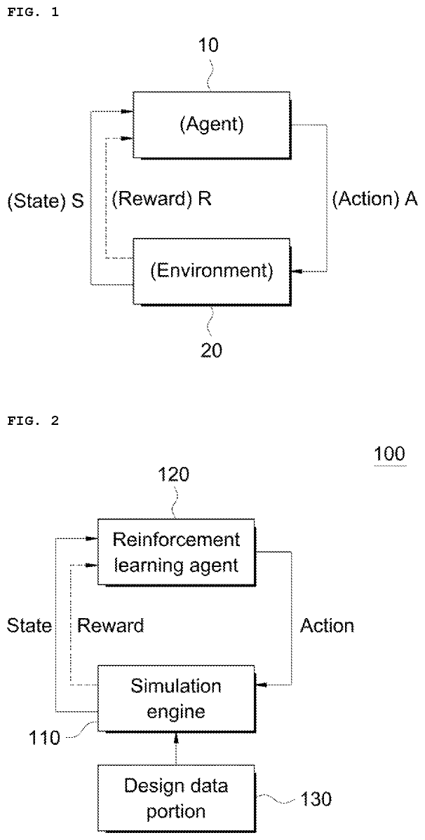

### DETAILED DESCRIPTION OF THE EXEMPLARY EMBODIMENTS

Hereinafter, the present disclosure will be described in detail with reference to exemplary embodiments of the present disclosure and the accompanying drawings, assuming that identical reference numerals in the drawings denote identical elements.

Prior to detailed descriptions for implementing the present disclosure, it is to be noted that elements having no direct relevance to the technical gist of the present disclosure will be omitted without obscuring the technical gist of the present disclosure.

In addition, terms or words used in the present specification and claims are to be interpreted in meanings and concepts conforming to the technical idea of the present disclosure according to the principle that the inventors may define appropriate concepts of terms to better describe the present disclosure.

As used herein, the description that a part “includes” an element means, without excluding other elements, that the part may further include other elements.

In addition, terms such as “ . . . portion”, “-er”, and “ . . . module” refer to units configured to process at least one function or operation, and may be distinguished by hardware, software, or a combination of the two.

In addition, the term “at least one” is defined as including both singular and plural forms, and it will be obvious that, even without the term “at least one”, each element may exist in a singular or plural form, and may denote a singular or plural form.

In addition, each element provided in a singular or plural foam may be changed depending on the embodiment.

Hereinafter, an exemplary embodiment of an apparatus and a method for reinforcement learning for semiconductor element position optimization based on semiconductor design data according to an embodiment of the present disclosure will be described in detail with reference to the accompanying drawings.

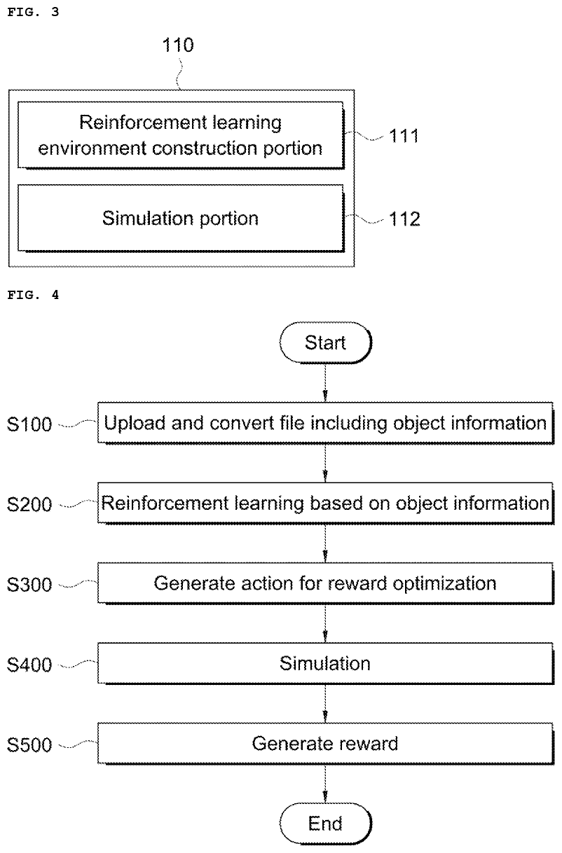

FIG. 2 is a block diagram illustrating the configuration of an apparatus for reinforcement learning for object position optimization based on semiconductor design data according to an embodiment of the present disclosure. FIG. 3 is a block diagram illustrating the configuration of a simulation engine of the apparatus for reinforcement learning for object position optimization based on semiconductor design data according to the embodiment in FIG. 2.

Referring to FIG. 2 and FIG. 3, the apparatus 100 for reinforcement learning for semiconductor element position optimization based on semiconductor design data according to an embodiment of the present disclosure may include a simulation engine 110 configured to construct a learning environment based on a user's semiconductor design data such that optimal positions of semiconductor elements can be generated and provided during a semiconductor design process through reinforcement learning using simulation, a reinforcement learning agent 120, and a design data portion 130.

The simulation engine 110 is configured to construct an environment for reinforcement learning, and may include a reinforcement learning environment construction portion 111 configured to construct a reinforcement learning environment by implementing a virtual environment in which learning proceeds while interacting with a reinforcement learning agent 120 through simulation regarding semiconductor element disposition based on actions received from the reinforcement learning agent 120, and a simulation portion 112.

In addition, the simulation engine 110 may have an API configured such that a reinforcement learning algorithm for training a model of the reinforcement learning agent 120 can be applied.

The API may deliver information to the reinforcement learning agent 120, and may perform an interface between programs, such as “Python”, for the reinforcement learning agent 120.

In addition, the simulation engine 110 may include a web-based graphic library (not illustrated) such that web-based visualization is possible, and may convert the same to an eXtensible Markup Language (XML) file such that the same can be used after web-based visualization.

That is, the simulation engine 110 may be configured such that interactive 3D graphics can be used in a compatible web browser.

The reinforcement learning environment construction portion 111 may analyze information regarding objects, such as semiconductor elements and standard cells, based on design data including semiconductor netlist information, thereby generating simulation data constituting a reinforcement learning environment and specific constraints with regard to respective objects.

The design data includes semiconductor netlist information, and includes information regarding semiconductor elements and standard cells supposed to enter a reinforcement learning state.

In addition, the netlist is a result obtained after circuit synthesis, and enumerates information regarding specific design elements and connectivity thereof. The same is used by circuit designers to make a circuit that satisfies a desired function. However, it is also possible to use a hardware description language (HDL) to implement the same, or to manually draw a circuit with a CAD tool.

If the HDL language is used, the same is used in a method easy to implement from a non-professional's point of view. Therefore, when actually applied to hardware, for example, when implemented as a chip, a circuit synthesis process is performed. The input and output of constituent elements, and the type of adder used thereby are referred to as a netlist. The result of synthesis may be output as a single file, which is referred to as a netlist file.

In addition, a circuit itself may be expressed as a netlist file when a CAD tool is used.

The netlist file made in this manner can be implemented as an actual chip through a layout.

In addition, design data may include individual files because individual constraints need to be configured after receiving information regarding respective objects, such as semiconductor elements and standard cells. The design data may preferably be configured as a semiconductor data file. The file type may be as follows: “.v” file, “ctl” file, or the like, which is composed by an HDL used for electronic circuits and systems.

In addition, the design data may be a semiconductor data file composed by the user such that a learning environment similar to the actual environment can be provided, or may be CAD data.

In addition, the reinforcement learning environment construction portion 111 may deliver state information to be used for reinforcement learning and reward information based on simulation to the reinforcement learning agent 120, and may request the reinforcement learning agent 120 to conduct an action.

That is, the reinforcement learning environment construction portion 111 may request the reinforcement learning agent 120 to provide optimization information for at least one semiconductor element disposition, based on simulation data constituting the generated reinforcement learning environment.

The simulation portion 112 may perform simulation regarding semiconductor element disposition, based on state information including semiconductor element disposition information to be used for reinforcement learning and the action received from the reinforcement learning agent 120, and may provide the reinforcement learning agent 120 with reward information according to the result of simulation as feedback regarding a decision making by the reinforcement learning agent 120.

The reward information may be calculated based on information regarding connection between semiconductor elements and standard cells.

The reinforcement learning agent 120 is configured to perform reinforcement learning, based on state information and reward information received from the simulation engine 110, and to determine an action such that semiconductor element disposition is optimized, and may include a reinforcement learning algorithm.

The reinforcement learning algorithm may use one of a value-based approach scheme and a policy-based approach scheme in order to find out an optimal policy for maximizing rewards. According to the value-based approach scheme, the optimal policy is derived from an optimal value function approximated based on the agent's experience. According to the policy-based approach scheme, an optimal policy separated from value function approximation is learned, and the trained policy is improved in an approximate value function.

In addition, the reinforcement learning algorithm is learned by the reinforcement learning agent 120 to be able to determine actions such that the distance between semiconductor elements, the length of a wire connecting a semiconductor element and a standard cell, and the like are disposed in optimal positions.

The design data portion 130 is configured to provide semiconductor design data including entire object information to the simulation engine 110, and may be a server system or a user terminal, in which semiconductor design data is stored.

In addition, the design data portion 130 may be connected to the simulation engine 110 through a network.

Next, a method for reinforcement learning for semiconductor element position optimization based on semiconductor design data according to an embodiment of the present disclosure will be described.

FIG. 4 is a flowchart illustrating a method for reinforcement learning for semiconductor element position optimization based on semiconductor design data according to an embodiment of the present disclosure.

Referring to FIG. 2 to FIG. 4, according to a method for reinforcement learning for semiconductor element position optimization based on semiconductor design data according to an embodiment of the present disclosure, if semiconductor design data is uploaded from the design data portion 130, the simulation engine 110 analyzes information regarding objects such as semiconductor elements and standard cells, based on design data including semiconductor netlist information, thereby generating simulation data constituting a reinforcement learning environment and specific constraints with regard to individual objects (S100).

That is, the design data uploaded in step S100 is a semiconductor data file, and includes information regarding semiconductor elements, standard cells, and the like supposed to enter a reinforcement learning state.

That is, in step S100, information of respective objects is received, and individual constrains are configured in design processes with regard to individual objects.

In addition, in step S100, after configuring constraints with regard to individual objects by using respective objects of the semiconductor data file, such as semiconductor elements and standard cells, the simulation engine 110 generates simulation data constituting a reinforcement learning environment by using the configured information as learning environment information.

In addition, in step S100, the simulation engine 110 may convert the same to an eXtensible Markup Language (XML) file such that the same can be used after web-based visualization.

Subsequently, the reinforcement learning agent 120 receives a request for optimizing semiconductor element disposition based on simulation data constituting a reinforcement learning environment from the simulation engine 110.

After receiving the request for optimizing semiconductor element disposition, the reinforcement learning agent 120 performs reinforcement learning based on reward information and state information including semiconductor element disposition information to be used for reinforcement learning, collected from the simulation engine 110 (S200).

That is, the reinforcement learning agent 120 disposes semiconductor elements by using a reinforcement learning algorithm, and learns to be able to determine an action such that distances from already disposed semiconductor elements, positional relation, lengths of wires connecting semiconductor elements and standard cells, and the like are disposed in optimal positions.

In addition, the reinforcement learning agent 120 determines an action such that semiconductor element disposition is optimized through reinforcement learning (S300).

Subsequently, the simulation engine 110 performs simulation regarding semiconductor element disposition, based on the action received from the reinforcement learning agent 120 (S400).

Based on the result of simulation in step S400, the simulation engine 110 generates reward information based on information regarding connection between semiconductor elements and standard cells (S500), and the generated reward information is provided to the reinforcement learning agent 120.

In addition, the reward information may have distances determined based on semiconductor element sizes.

Therefore, the simulation engine 110 provides the reinforcement learning agent 120 with states including environment information, and the reinforcement learning agent 120 determines an optimal action through reinforcement learning based on the provided states. Then, the simulation engine 110 generates a reward regarding the simulation result through action-based simulation and provides the same to the reinforcement learning agent 120 such that the reinforcement learning agent 120 can reflect the reward information and determine the next action.

In addition, optimal positions of semiconductor elements may be generated and provided during semiconductor design processes through reinforcement learning using simulation after constructing a learning environment based on the user's semiconductor design data.

In addition, a learning environment similar to the actual environment may be provided based on data designed by the user while the user conducts semiconductor design, thereby improving design accuracy, and optimized target object positions may be automatically generated through reinforcement learning based on data designed by the user, thereby improving work efficiency.

The present disclosure has been described above with reference to exemplary embodiments, but those skilled in the art will understand that the present disclosure can be variously changed and modified without deviating from the idea and scope of the present disclosure described in the following claims.

In addition, reference numerals used in the claims of the present disclosure are only for clarity and convenience of description and are not limiting in any manner, and the thickness of lines illustrated in the drawings, the size of elements, and the like may be exaggerated for clarity and convenience of description in the process of describing embodiments.

In addition, the above-mentioned teams are defined by considering functions in the present disclosure, and may vary depending on the intent of the user or operator, or practices. Therefore, such terms are to be interpreted based on the overall context of the specification.

In addition, although not explicitly described or illustrated, it is obvious that those skilled in the art to which the present disclosure pertains can make various types of modifications, including the technical idea of the present disclosure, from descriptions of the present disclosure, and such modifications still fall within the scope of the present disclosure.

In addition, the embodiments described above with reference to accompanying drawings are only for describing the present disclosure, and the scope of the present disclosure is not limited to such embodiments.

### Brief Description of Reference Numerals

100: reinforcement learning apparatus
110: simulation engine
111: reinforcement learning environment construction portion
112: simulation portion
120: reinforcement learning agent
130: design data portion

What is claimed is:

1. An apparatus for reinforcement learning for semiconductor element position optimization based on semiconductor design data, the apparatus comprising:
a simulation engine (110) configured to analyze object information comprising a semiconductor element and a standard cell based on design data comprising semiconductor netlist information, generate simulation data constituting a reinforcement learning environment having specific constrains configured with regard to individual analyzed objects, request optimization information for at least one semiconductor element disposition, perform simulation regarding disposition of the semiconductor element and the standard cell based on an action received from a reinforcement learning agent (120) and state information comprising disposition information of the semiconductor element and the standard cell to be used for reinforcement learning, and provide reward information calculated based on connection information of the semiconductor element and the standard cell according to a simulation result as feedback regarding decision making by the reinforcement learning agent (120);
a reinforcement learning agent (120) configured to perform reinforcement learning based on state information and reward information received from the simulation engine (110), thereby determining an action so as to optimize disposition of the semiconductor element and the standard cell; and
a design data portion (130) configured to provide design data comprising semiconductor netlist information to the simulation engine (110),
wherein the simulation engine (110) generates, as reward information, distances by considering semiconductor element sizes according to a simulation result and provides the reward information to the reinforcement learning agent (120), and
wherein the reinforcement learning agent (120) determines an action through learning using a reinforcement learning algorithm such that the semiconductor elements are disposed in optimal positions, by reflecting the reward information in distances from already-disposed semiconductor elements, positional relation, and lengths of wires connecting semiconductor elements and standard cells.

2. The apparatus for reinforcement learning for semiconductor element position optimization based on semiconductor design data of claim 1, wherein the design data is a semiconductor data file comprising CAD data or netlist data.

3. The apparatus for reinforcement learning for semiconductor element position optimization based on semiconductor design data of claim 1, wherein the simulation engine (110) has an application program additionally installed for web-based visualization.

4. The apparatus for reinforcement learning for semiconductor element position optimization based on semiconductor design data of claim 1, wherein the simulation engine (110) comprises:
a reinforcement learning environment construction portion (111) configured to analyze object information comprising semiconductor elements and standard cells based on design data comprising semiconductor netlist information, generate simulation data constituting a reinforcement learning environment and specific constraints with regard to individual objects, and request the reinforcement learning agent (120), based on the simulation data, to provide optimization information for at least one semiconductor element disposition; and
a simulation portion (112) configured to perform simulation regarding disposition of semiconductor elements and standard cells based on actions received from the reinforcement learning agent (120), calculate reward information based on connection information of the semiconductor elements and the standard cells according to a simulation result as feedback regarding decision making by the reinforcement learning agent (120) and state information comprising disposition information of semiconductor elements and standard cells to be used for reinforcement learning, generate, as the reward information, distances by considering semiconductor element sizes according to the simulation result, and provide the reward information to the reinforcement learning agent (120).

5. The apparatus for reinforcement learning for semiconductor element position optimization based on semiconductor design data of claim 4, wherein the reward information is calculated based on connection information of semiconductor elements and standard cells.

6. A method for reinforcement learning for semiconductor element position optimization based on semiconductor design data, the method comprising the steps of:
a) analyzing, by a simulation engine (110), object information comprising a semiconductor element and a standard cell when design data comprising semiconductor netlist information is uploaded, thereby generating simulation data constituting a reinforcement learning environment having specific constrains configured with regard to individual analyzed objects;
b) performing reinforcement learning, by a reinforcement learning agent (120), based on reward information and state information comprising disposition information of the semiconductor element and the standard cell to be used for reinforcement learning, collected from the simulation engine (110), upon receiving an optimization request for disposition of the semiconductor element and the standard cell based on simulation data constituting a reinforcement learning environment from the simulation engine (110), thereby determining an action so as to optimize disposition of the semiconductor element and the standard cell; and
c) performing, by the simulation engine (110), simulation constituting a reinforcement learning environment regarding the semiconductor element and the standard cell based on an action received from the reinforcement learning agent (120), and providing the reinforcement learning agent (120) with state information comprising disposition information of the semiconductor element and the standard cell to be used for reinforcement learning, and reward information calculated based on connection information of the semiconductor element and the standard cell according to a simulation result as feedback regarding decision making by the reinforcement learning agent (120),
wherein the simulation engine (110) generates, as reward information, distances by considering semiconductor element sizes according to the simulation result and provides the reward information to the reinforcement learning agent (120), and
wherein the reinforcement learning agent (120) determines an action through learning using a reinforcement learning algorithm such that the semiconductor elements are disposed in optimal positions, by reflecting the reward information in distances from already-disposed semiconductor elements, positional relation, and lengths of wires connecting semiconductor elements and standard cells.

7. The method for reinforcement learning for semiconductor element position optimization based on semiconductor design data of claim 6, wherein the design data in step a) is a semiconductor data file comprising CAD data or netlist data.

8. The method for reinforcement learning for semiconductor element position optimization based on semiconductor design data of claim 6, further comprising a step of converting the simulation data in step a) to an eXtensible Markup Language (XML) file to be used through a web.
